(19) United States
(12) Patent Application Publication
(10) Pub. No.: US 2015/0185285 A1
(43) Pub. Date: Jul. 2, 2015

(54) SYSTEM AND METHOD FOR REDUCED PIN LOGIC SCANNING

(71) Applicant: SanDisk Technologies Inc., Plano, TX (US)

(72) Inventors: Vladimir Kovalev, Union City, CA (US); Sharon Mutchnik, San Jose, CA (US)

(21) Appl. No.: 14/143,821

(22) Filed: Dec. 30, 2013

(51) Int. Cl. G01R 31/317; G01R 31/3177

(52) U.S. Cl. CPC G01R 31/31713; G01R 31/3177

(57) ABSTRACT

A system and method for reduced scan pin logic scanning is provided. The system may include a reduced test pin integrated circuit having at least one scan chain comprising a plurality of sequentially connected flip-flop circuits. Digital logic circuitry (also referred to as random logic) is connected to at least one of the plurality of flip-flop circuits in the at least one scan chain. Combined test data pins, with separate clock and scan enable pins are contemplated, as well as additional internal circuitry for the integrated circuit that can eliminate a separate scan enable pin, or both the separate scan enable and clock pins. Circuitry for permitting simultaneous test data input and output on the same pin is also contemplated.

### BACKGROUND

Semiconductor manufacturing techniques vary both for creating an initial wafer of multiple integrated circuit die and for packaging individual die from a wafer into integrated circuit packages for shipment. It is expected that a certain number of defects will appear in semiconductor devices both at the wafer manufacturing stage and in the packaging of the die that are cut from the individual wafers. Due to the prevalence of errors introduced into integrated circuits both at the wafer stage and at the individual integrated circuit packaging stage, tests are typically necessary to identify errors and weed out bad components. Digital logic circuitry, such as flip-flops, and logic gates (e.g., AND, OR, NAND, NOR etc.) can all be tested prior to, and after, packaging of the individual dies from wafers. In a typical arrangement, the tests for these circuits require four input pins: one each for test data input, test data output, a clock signal and a test enable signal. Access to different parts of an integrated circuit to test the logic circuitry is relatively straightforward when a die is unpackaged. Once a die is packaged, however, the space for, and access to, the necessary inputs for testing may be limited. Additionally, the expense of providing externally accessible inputs for the various signals needed to execute a test may be difficult or expensive given limited physical space available and the cost of packaging. Opening packaged circuits, even in a manner where only a certain portion of packaged circuitry is opened up for testing, can be costly and time consuming.

### SUMMARY

In order to address issues of testing logic circuits and accessibility to inputs for testing logic circuits, a system and method for reducing pin inputs to test logic circuits is discussed herein.

According to a first aspect, an integrated having a reduced number of test pins is described. The integrated circuit may include at least one scan chain, the at least one scan chain comprising a plurality of sequentially connected flip-flop circuits. Digital logic circuitry (also referred to as random logic) is connected to at least one of the plurality of flip-flop circuits in the at least one scan chain. A clock input pin is configured to receive an externally generated clock signal from an external test device. Additionally, a test data pin is configured to receive test input data from the external test device and to receive test output data generated internally at the integrated circuit by the at least one scan chain, the test output data corresponding to the received test input data after clocking the test input data through the scan chain.

In one implementation an input-output control circuit may be connected to the test data pin, where the input-output control circuit is configured to toggle a mode of the test data pin between an input-only mode, wherein test input data from the external test device is applied to the scan chain, and an output-only mode, wherein test output data generated by the scan chain is applied to the test data pin. In different variations, the integrated circuit may either be set into a test mode through use of a test scan enable signal from the external test device via a scan enable signal pin on the integrated circuit, or may do without a separate scan enable pin by internally generating the scan enable signal in an internal scan enable signal circuit using the received clock signal.

According to another aspect, a reduced test pin integrated circuit includes a scan chain, the scan chain comprising a plurality of sequentially connected flip-flop circuits, where digital logic circuitry is connected to at least one of the plurality of flip-flop circuits, and a single external test pin in communication with the scan chain via a first signal generation circuit and a second signal generation circuit. The output of the first signal generation circuit is in communication with a clock input of the plurality of flip-flop circuits in the scan chain and is responsive to receipt of a signal at the single external test pin having at least a first voltage level to generate a clock pulse for the plurality of flip-flop circuits. The output of the second signal generation circuit is in communication with a data input of only a first of the plurality of flip-flop circuits and the second signal generation circuit is responsive to receipt of the signal at the single external test pin to generate a logical high input for the first flip-flop circuit only when the signal has at least a second voltage level that is greater than the first voltage level. A third signal generation circuit internal to the integrated circuit may also be included to provide another mechanism from generating a scan enable signal from the single test input.

In different aspects, any of the above embodiments may use simultaneous input and output of test data over a single pin using a current sensing arrangement connected to an output of the last flip-flop in the scan chain. Furthermore, methods of testing scan chains in integrated circuits using the reduced test pin integrated circuit designs described above are contemplated.

### BRIEF DESCRIPTION OF THE DRAWINGS

FIG. 1 is a block diagram of a standard external testing device using a four external pin test arrangement on an integrated circuit package for testing logic chains.

FIG. 2 illustrates the testing clock and signal activity usable in the integrated circuit package of FIG. 1.

FIG. 3A is a block diagram of an external testing device testing a integrated circuit package having three test pins for testing logic chains.

FIG. 3B is a circuit diagram of an embodiment of an integrated circuit configured to reduce a number of test pins necessary to test logic circuitry.

FIG. 4 illustrates the testing clock and signal activity usable with the reduced test pin embodiment of FIGS. 3 and 5.

FIG. 5A is a circuit diagram of an alternative embodiment of the integrated circuit of FIG. 3 illustrating an integrated circuit package with a further reduction in the number of test pins necessary to test logic circuitry.

FIG. 5B is a circuit diagram of the embodiment of FIG. 5A showing an integrated circuit configured to reduce a number of test pins necessary to test logic circuitry.

FIG. 6 is a simplified circuit diagram of an alternative embodiment of the two test pin integrated circuit of FIG. 5 illustrating an integrated circuit having simultaneous input and output test data capabilities over a single data pin.

FIG. 7 illustrates the testing clock and signal activity usable with the reduced test pin embodiment of FIG. 6.

FIG. 8 illustrates an output current sense table for interpreting the output test values from the last flip-flop in the scan chain in the embodiment of FIG. 6.

FIG. 9A illustrates a single test pin embodiment integrated circuit and external testing device.

FIG. 9B is a circuit diagram of the embodiment of FIG. 9A showing an integrated circuit configured to reduce a number of test pins necessary to test logic circuitry to a single pin and utilizing the current sense test output configuration of FIG. 6

FIG. 10 illustrates an internal logic trigger diagram associated with the integrated circuit of FIG. 9B.

FIG. 11 illustrates a sample input signal set and corresponding internal signal generation scheme of the single test pin integrated circuit of FIGS. 9A-9B.

FIG. 12 is a circuit diagram of an alternative embodiment of the single test pin integrated circuit of FIG. 9.

FIG. 13 illustrates an internal logic trigger diagram associated with the integrated circuit of FIG. 12.

FIG. 14 illustrates a sample input signal set and corresponding internal signal generation scheme of the single test pin integrated circuit of FIG. 12.

FIG. 15 is a flow diagram of testing a single test pin integrated circuit such as shown in FIG. 9 or 12.

### DETAILED DESCRIPTION

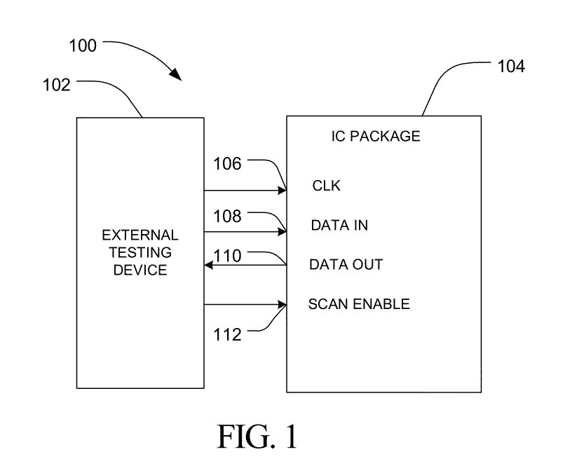

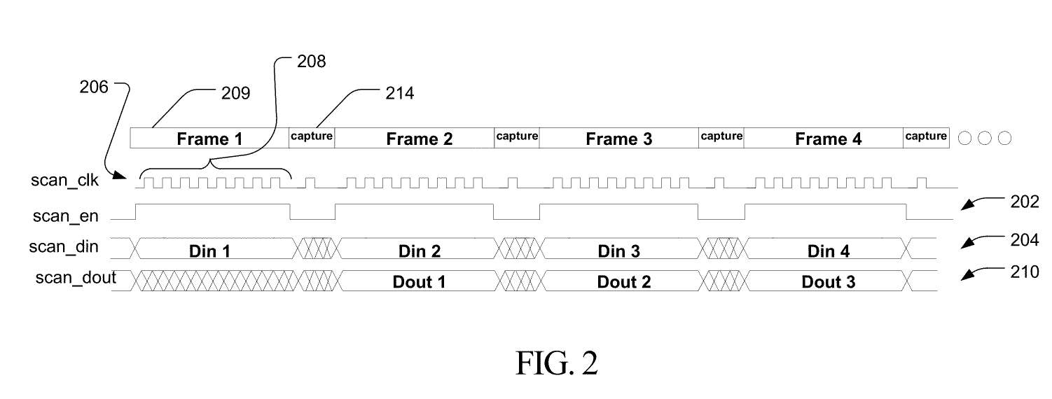

In the various logic circuit arrangements and testing schemes described herein, a reduced number of pin out requirements and externally provided data connections are described to test for checking digital logic functions. Referring to FIGS. 1 and 2, a generic test bed 100 is illustrated along with the input and output traces for scanning logical data are shown. In the test bed 100 of FIG. 1, an external testing device 102 is shown connected to a standard integrated circuit package 104 under test. The integrated circuit package includes a clock input 106, a data in input 108, a data out pin 110, and a scan enable pin 112. FIG. 2 illustrates a hypothetical arrangement of inputs and outputs for these four pins in the IC package 104 of FIG. 1. A scan enable signal (scan_en) 204 illustrates the digital signal input for enabling scanning behavior of the target IC package 104. The scan enable signal 204 is applied to the scan enable pin 112 followed shortly thereafter by input scan data (scan_din) 206 and the clock signal (scan_clk) 202 applied to the clock pin 106 on the IC package 104 under test.

In preparation for the test, the external testing device 102 must be programmed with the number of sequential flip-flops being tested in the scan chain within the IC package 104. This number of flip-flops (i.e. scan chain length) will then be reflected in the number of pulses 210 introduced in the scan clock 202 signal. Matching the number of clock pulses to the number of flip-flops allows for the clocking in of a predetermined data input sequence for which a predetermined output is expected. The scan output information (scan_dout) 208 illustrates the output that is received at the data out pin 110 of the IC package 104.

The data in the output scan 208 for Frame 1 in FIG. 2 is shown as crossed out because the data clocked out from the scan chain at the same time the initial test data (Din 1) is clocking in is unrelated to Din 1 and do not reflect the test results for Din 1. Starting with Frame 2 of the input scan data Din 2, the output data (Dout 1) will reflect the test result for data entered on the previous frame (Din 1). This staggered relationship of the input data and the output data continues until the last input data for a sequence of logic testing needed for the scan chain is clocked in, at which point a subsequent series of data input pulses (not necessarily related to any testing sequence of data for which a known output is expected) may be entered in the data input pin in order to clock out the test results from the last input test sequence for which a test result is desired.

Between each frame 209 of test input data clocked into the IC package 104 under test, a capture period 214 is provided where an extra clock pulse is introduced when the scan enable signal 202 is kept low. This capture period 214 permits one more extra data shift into the data pin for each of the flip-flops in the chain. The different input test data provided by the external testing device 102 on the scan data in port 108 may vary for as many frames as necessary to test out all the possible combinations that a manufacturer wishes to test for the chain of logic gates in the integrated circuit.

### Reduction of External Test Pins to 3

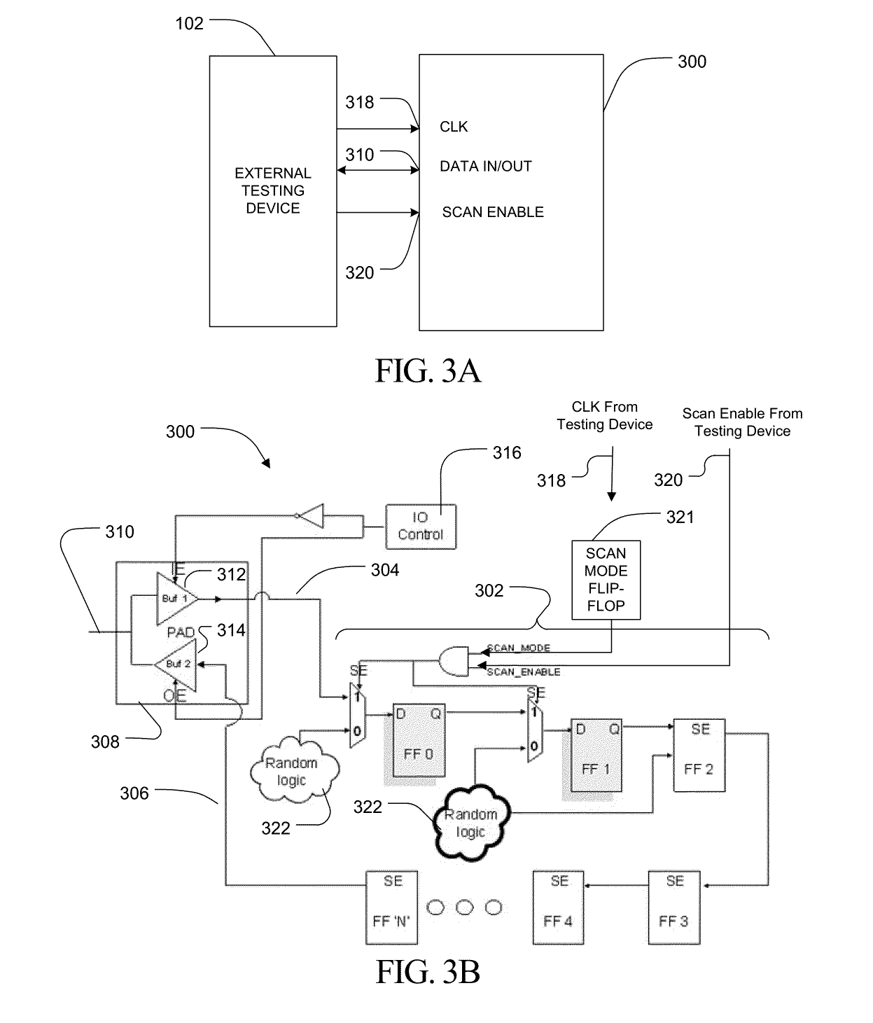

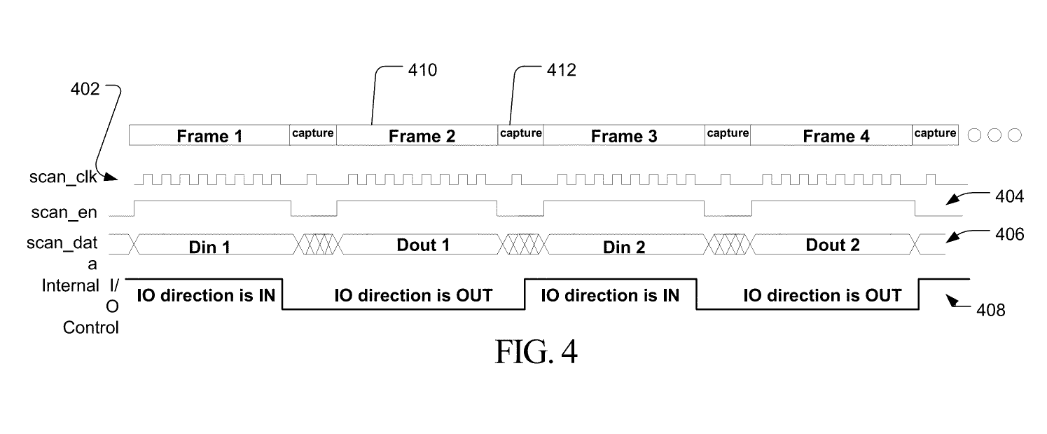

The example of FIGS. 1 and 2 illustrate an integrated circuit design with four external scan pins, which has generally been the minimum number of pins required for testing. The integrated circuit package 104 may contain more than one scan chain and the one or more scan chains may be separately tested (i.e., the scan chains switched between the same four pins) via compression, internally shifting and other known techniques. Referring now to FIGS. 3A-3B and 4, an embodiment of a reduced scan pin structure and method for testing is illustrated. In the embodiment of FIGS. 3A-3B and 4, the number of test pins is reduced from four down to three. The reduction of pins in this embodiment is accomplished by combining the data in and data out pins of FIG. 1 into a single pin.

Referring to the IC package 300 of FIGS. 3A-3B, a scan chain 302 in the package 300 is illustrated that includes random logic 322 and a series of serially connected flip-flops (FF 0-FF N). Inside the IC package 300, input line 304 for the scan chain 302 and an output line 306 for the scan chain 302 connect to an input/output pad 308 having a single external pin connection 310 with which a test device would both enter and retrieve test data. The input/output pad 308 includes an input buffer 312 and an output buffer 314 which are controlled by an I/O (input/output) control circuit 316. The I/O control circuit 316 is configured to internally generate an I/O control signal that allows data to either be input or output via synchronous with the scan clock information received from an external scan clock pin 318. The I/O control circuit only permits one-way communication via the pin 310 at any given time. An external scan enable pin 320 receives from the external testing device the scan enable signal synchronized with input data that the external testing device is providing to the input/output pin 310 or with output data the external testing device is expecting to receive from the input/output pin 310. It is evident from the single input/output pin 310 and pad 308 structure of the circuit in FIGS. 3A-3B, that test data may only move in one direction at a time such that input test data may be put in during one sequence of scan clock pulses and output data may be read out during a separate sequence of scan clock pulses.

Referring to FIG. 4, the signals at the three external pins (data input/output pin 310, external clock pin 318 and scan enable pin 320) are shown at the data activity trace (scan_data) 406, on the external clock signal (scan_clock) 404, and scan enable signal (scan_en) 404, respectively. Also shown in the sequence of signals in FIG. 4 is the internally generated input/output control from the I/O control circuit 316 that is generated based on the external clock signal 402. The I/O control circuit 316 may operate in concert with a simple divider circuit, for example an arrangement of flip-flops separate from the flip-flops in the scan chain 302, that is arranged to generate an I/O control signal 408. The I/O control signal 408 generated by I/O control circuit 316 is a signal that alternates between periods having a logical high and a logical low, where the individual duration of each of the logical high or logical low states is in a time increment that corresponds to a number of flip-flops in the scan chain for the integrated circuit.

In the example of FIG. 4, when the I/O control signal 408 is high, the input buffer 312 is enabled to permit data input from the external testing device (I/O direction is in only), and when the I/O control circuit 316 generates a logical low, this activates the output buffer 314 of the input/output pad circuit 308 for the data to be read out (I/O direction is out only). An advantage of the three pin testing arrangement of FIG. 3 is a reduction in the number of pins necessary to perform a test. Although, compared to the four pin test example of FIGS. 1-2, the data flow is reduced in this embodiment because data may only be read in or read out in alternate bursts off of a single data input/output pin 310, the space savings and cost savings may be significant.

Referring again to FIG. 3B, the test mode for the scan chain 302 may be set by the external scan enable signal at the scan enable pin 320 in concert with the integrated circuit being in a scan mode such that the circuit is in a test mode. In one implementation, the scan mode may be enabled by addressing a dedicated flip-flop 321 that is located outside of the scan chain being tested. The dedicated flip-flop 321 may be addressed with a logical “1” so that subsequent input at the external scan enable pin 320 will result in initiating test activity and spurious switching between a testing state and an active state of the integrated circuit can be avoided. The scan mode bit setting of “1” (logical high) may be set via a command given to device firmware/software, directly from an external device interface, or in any of a number of other known ways such that the logic “1” setting in the flip-flop 321 cannot be altered until the integrated circuit 300 is reset. It is contemplated that, in one embodiment, the dedicated flip-flop 321 configured to enable the scan mode in the integrated circuit may only be reset by resetting the entire integrated circuit through a power cycling, at which point the flip-flop 321 returns to a default logic low (“0”).

In the illustration of FIG. 3B, the first flip-flops (FF 0 and FF 1) are shown with connections to random logic 322. The random logic may represent any of a number of logic gates, such as AND, OR, NAND, NOR and so on, that do not individually hold states, but instead affect the logic state (i.e., a 0 or a 1) that is input to the next flip-flop in the scan chain and eventually clocks out from the last flip-flop (FF N), after passing through the various random logic 322 circuitry of each flip-flop in the chain 302, as the output test data sent to the testing device 102. It is intended that each flip-flop, from flip-flop 2 through the end of the scan chain (FF 2-FF N), may also be associated with respective or shared random logic and various connections (not shown) between flip-flops that can result in different outputs for various inputs. It is this collection of possible different outputs for possible different inputs that may require the external testing device, for a given scan chain 302, to input multiple combinations of input bits, each in a different frame, to test out all the known expected outputs for a particular combination of connections of random logic to the flip-flops in the scan chain 302.

### Reduction of External Test Pins to 2

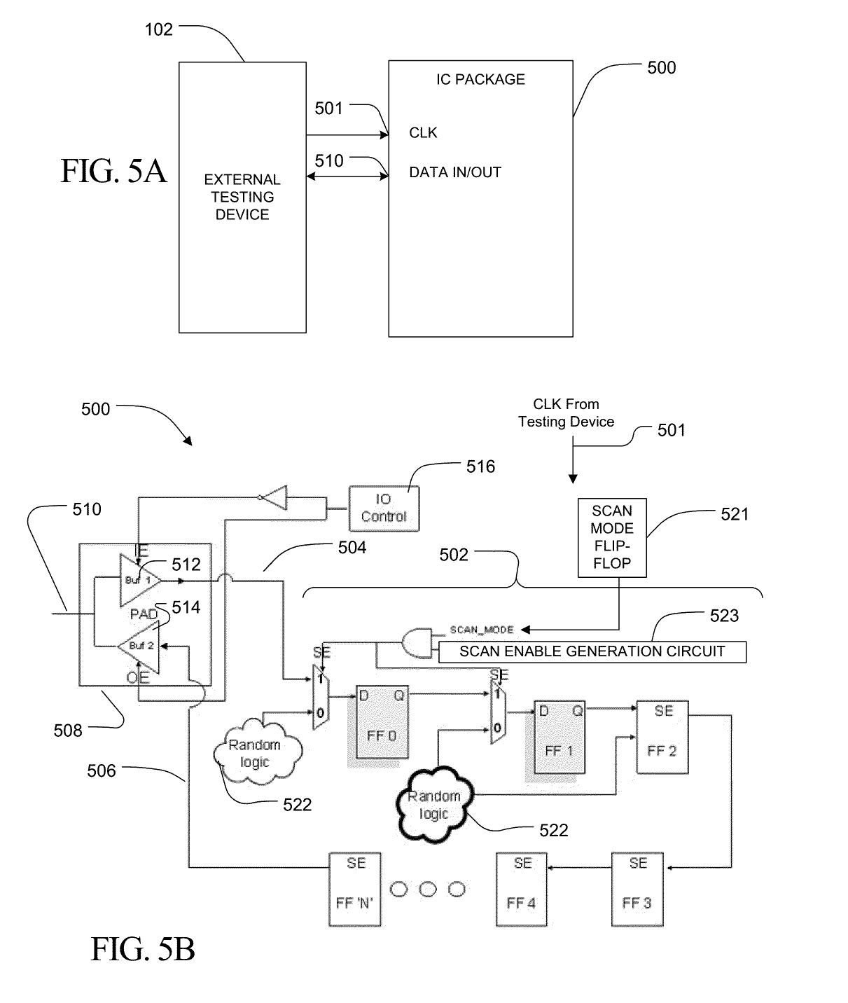

In addition to reducing the number of test scan pins required from four down to three (310, 318, 320) as illustrated in the embodiment of FIGS. 3A-3B and 4, a further embodiment is contemplated where an additional external pin may be omitted. As illustrated in FIGS. 5A-5B, a circuit similar to FIGS. 3A-3B, but lacking a separate external scan enable pin is illustrated. The scan enable pin 320 of the embodiment of FIGS. 3A-3B may be avoided by adding internal scan enable circuitry 523 to the integrated circuit of FIG. 5. The internal scan enable circuitry 523 may be in the form of standard divider or counter circuitry that synchronizes the scan enable signal with the external clock signal for the predetermined number of clock pulses necessary to clock in or out data for testing random logic 522 for a complete scan chain 502 of flip-flops (FF0 to FF N). Thus, the difference between the integrated circuit of FIGS. 5A-5B and the integrated circuit of FIGS. 3A-3B is the removal of an external scan enable pin and the introduction, along the scan clock signal line within the integrated circuit, of further divider circuitry and/or counters having desired transition times and spaces between enabling input and output to permit data capture periods in between.

Referring again to FIG. 4, signals associated with a hypothetical testing of a circuit such as shown in FIG. 5 are essentially the same as described for the circuit design of FIG. 3. The only difference being the internal generation of the scan_enable 404 signal using the clock signal 402, instead of receiving a separate external scan enable signal from the testing device 102. Thus, the only externally provided test signals needed for the embodiment of FIGS. 5A-5B are the scan_clk 402 signal and the input data in the scan_data signal 406. The scan enable signal 404 is generated internally by the internal scan enable generation circuit 523. As a result of the internal scan enable signal generation, a further pin may be removed for external input or output for testing.

Referring again to FIG. 4, for both the embodiments of FIGS. 3 and 5, the sequence of events for testing an integrated circuit may be described as follows. The testing sequence may begin after a scan mode bit is stored in a register or flip-flop 521 by the testing device 102. Subsequently, upon entering the testing mode, the integrated circuit the I/O control circuit 316, 516 enables the input buffer 312, 512 for the input/output pad 308, 508. Once a counter in the I/O control circuit 316, 516 has counted the number of clock pulses corresponding to the length of the scan chain 302, 502 (i.e., equal to the number of flip-flops being tested in the chain) the I/O control circuit 316, 516, upon the negative edge of the clock pulse 402, 602, will switch from input mode to output mode so that data may only be read out from the integrated circuit 300, 500. The I/O control circuit 316, 516 in the integrated circuit 300, 500 will next count the number of capture or clock pulses (which may be one or more depending on the number of pulses necessary for the flip-flops in the scan chain to store the individual bits), in addition to the scan chain length. At the negative edge of a pulse in the clock signal 402 after the end of that sum of scan chain length plus capture counts (corresponding to the number of clock pulses encompassed by Frame 2 410 and capture 412 periods, the input/output control signal 408 will switch back from output mode to input mode to activate the input buffer in the input/output pad 308. The difference in functionality between the circuit 300 of FIGS. 3A-3B and the circuit 500 of FIGS. 5B-5B being that the scan enable signal 402 would be externally provided by a testing device for the 3 external pin embodiment of FIGS. 3A-3B, and internally generated by the 2 external pin embodiment of FIGS. 5A-5B.

It should be noted that, in one embodiment, the integrated circuit under test may have more than one scan chain and each of these scan chains may be independently tested. During testing, each scan chain may be connected to the same enabling circuitry and mode setting circuitry along with the same clock input circuitry. So that different scan chains may be tested at the same time, the number of clock cycles used for testing each frame as illustrated in FIG. 4 can be set to the number of clock cycles necessary to clock data through the longest of the scan chains. For those scan chains in the integrated circuit having fewer flip-flops than in the longest scan chain, the external test device may clock in placeholder data for the bits which are not being tested prior to clocking in the test data later in the chain of clock pulses. In one embodiment, the test data for the shorter scan chains may be preceded by a string of 0's before storing the string of test data for that scan chain. All the different scan chains in a particular integrated circuit package may be tested in parallel even though the length of each test chain may differ. The scan enable and clock signals may be shared for all scan chains in the integrated circuit in this scenario, however each scan chain would be connected to a separate input/output pin in one implementation.

Again with reference to FIG. 4, for a multi-chain integrated circuit the scan enable signal 404, whether received from the external test device as in the example of FIGS. 3A-3B or internally generated as in the example of FIGS. 5A-5B the test process begins where, upon entering a scan mode enable state for the integrated circuit, the scan enable 404 is a default logical high level. A counter will then count the number of clock cycles for the length of the longest scan chain 302, 502. Once the count value for the clock has reached a number of scan chain flip-flops, at the negative edge of that scan clock pulse, the scan enable is lowered to a logical low level. The predetermined number of capture phase clock cycles is then counted and, once reached, the negative edge of the last capture phase 412 clock cycle causes the scan enable signal 404 to go a logical high again. During the scan enable high phase of a frame, when the input/output pad 308, 508 has the input buffer 312, 512 enabled, the scan chain 302, 502 is fed with test data from the external test device. While the scan enable 404 is at a logical high setting and the input/output pad 308. 508 has the output buffer 314, 514 powered, the scan chain 302, 502 is fed with a constant default value (which may be 0 or 1).

Referring again to the embodiments of FIGS. 3 and 5, the counters and flip-flops of the input/output control logic 316, 516, and any associated hardware inside the integrated circuit 500 that supports the settings of the internally set scan enable mode of FIG. 5, are not included in the one or more scan chains in the integrated circuit. The scan chain 302, 502 of flip-flops and random logic being tested must be discrete groups that do not include the counters, flip-flops and other logic circuits being used to test those scan chains. It is contemplated that the methods and circuit configurations above may be used to support various types of testing scans. For example, fault scans, at-speeds scans, transition scans and IDDQ scans, along with other commonly known test types are contemplated.

### Concurrent Data Input and Output Via Single External Data Pin

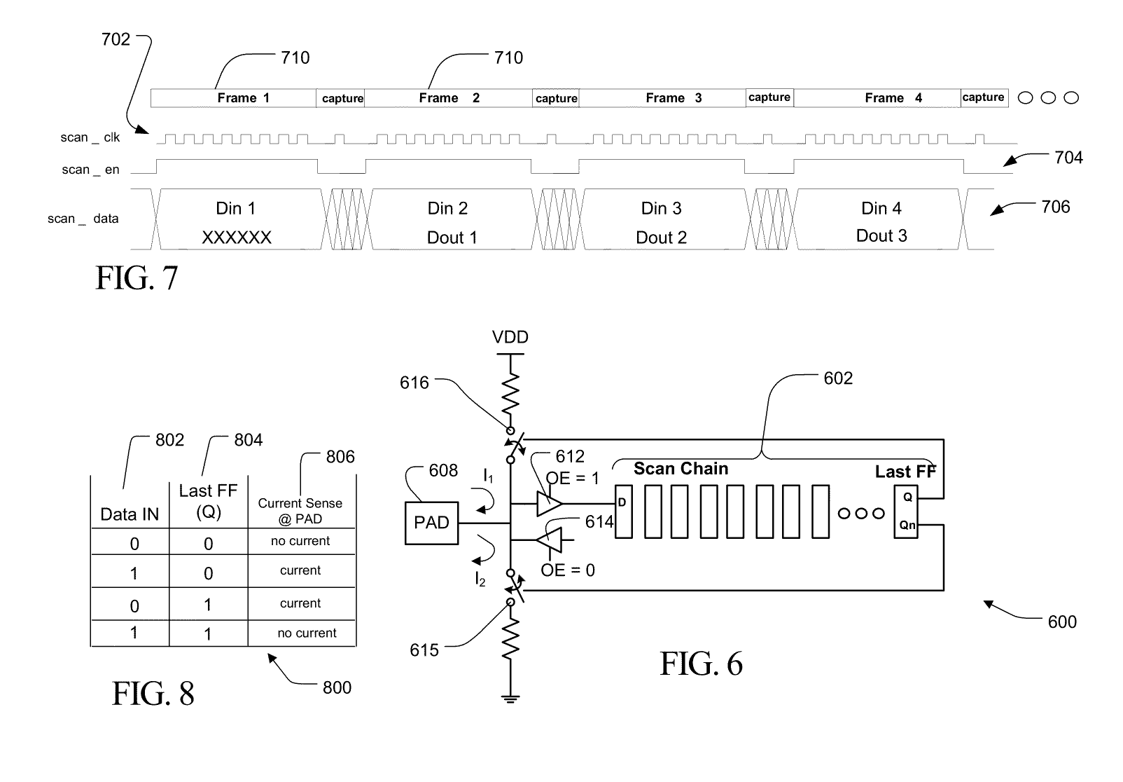

As a further enhancement to the test mechanisms and structures disclosed in FIGS. 3-5, a method of increasing test speed is contemplated. Because the implementations of FIGS. 3 and 5 require alternatively accepting input test data and outputting results of the tests over a single shared pin 310, 510, testing, although requiring fewer pins than a standard four pin arrangement shown in FIG. 1, may be slower than desired. One mechanism for essentially doubling the speed of testing in a reduced pin test arrangement is described with respect to FIGS. 6-8.

Referring first to FIG. 6, an integrated circuit 600 permitting concurrent test input and output data is illustrated. The integrated circuit 600 is a simplified integrated circuit version of the integrated circuit 300, 500 of either FIG. 3 or 5, showing only a sample scan chain 602 having a plurality of flip-flop circuits. The integrated circuit 600 also includes, but omits for clarity, the clock input and the scan enable circuitry (either an external scan enable pin 320 as in FIG. 3 or an internal scan enable signal generation circuit 523 as in FIG. 5) of the embodiments of FIGS. 3 and 5. Instead of requiring alternating input streams and output streams of data, the scan chain 602 in the integrated circuit 600 of FIG. 6 only connects to an activated input buffer 612. An output buffer 614 is not used and is illustrated as disconnected for comparison with the prior embodiments.

The circuit 600 of FIG. 6 is configured to receive voltage inputs at the single input/output pad 608 and provide a current output from the last flip-flop (Last FF) of the scan chain 602 to the input/output pad 608. This allows an external testing device 102 connected to the integrated circuit 600 to measure current outputs each clock cycle representing the value of the output of the last flip-flop in the scan chain 602 concurrently with providing voltage level input data via the pad 608. The output current measurements may be made by an external ammeter in communication with the testing device 102, or may be an ammeter built into the testing device 102 itself. The integrated circuit 600 simply uses feedback data from last flip-flop in the scan chain 602 to control pull-up & pull-down circuitry 615, 616 at the pad 608. By sensing current through an external driver, e.g. an ammeter, the shifted out test scan data can be captured via the shifts in current while voltage signals carrying the input test data are simultaneously being received at the pad 608. The pull-up and pull-down circuitry 616, 615 may be any of a number of standard pull-up and pull-down circuits.

Again, the modified input/output structure of FIG. 6 may be substituted for the input/output circuitry of the two test pin integrated circuit 500 of FIG. 5 where an external clock and external data input/output are received on an integrated circuit having two external pins and the scan enable signal is internally generated. Alternatively, the modified test data input/output configuration of FIG. 6 may be incorporated in an integrated circuit 300 having the three external test pin configuration of FIG. 3, where three separate external pins for clock, scan enable and data signals are implemented. FIG. 7 illustrates sample testing input and output signals for integrated circuits using either of the two combinations of two or three external pins and the concurrent voltage input and current output of test data discussed with respect to FIG. 6. By sensing current changes from the outputs of the last flip-flop at the input/output pin (pad 608), the scan data trace 706 may include simultaneous data input and output transmission in each frame 710. The data output in the first frame (Frame 1 in FIG. 7), when the initial data is input, may be spurious data because the scan chain would not have processed the input data that had just been clocked in, or it may be default data generated specifically at power up of the integrated circuit. However, the remaining frames 710 (Frame 2-Frame 4) in FIG. 7 illustrate valid data in and data out simultaneously (e.g. Din 2 and Dout 1) where the data out for a particular frame represents the output received for the data input from the prior frame. Thus, the time for testing a scan chain may be reduced by approximately half, compared with the integrated circuit arrangements of FIGS. 3 and 5, given the ability to simultaneously read some data while inputting other data into the scan chain.

Referring to the state table 800 of FIG. 8, the test input data voltage state (Data IN) 802, last flip-flop output signal (Last FF(Q)) 804, and resulting current sense 806 at the combined input/output pad 608 are shown. If the input data received at the single data input/output pad 608 from an external testing device is at a logical zero and the Q output of the last flip-flop (Last FF) is a logical zero then no current should be sensed at the pad 608. If the data voltage at the input pad 608 is at a level for a logical 1, and the last flip-flop is at a logical 0 (i.e., Qₙ is active low) then a pull down circuit 615 in the integrated circuit 600 would be expected to induce a current I₂ the pad. If the data input is a logical zero and the last flip-flop is a logical one (where Q is active high) then a current I₁ is induced at the input/output pad by the pull-up circuit 616. Alternatively, if the data input is logical one and the last flip-flop output is also a logical one then no current is induced at the pad 608. Using this table 800 of expected currents, the zero or one test data output can be sensed by the external testing device 102 while the external testing device 102 is inputting various voltages. This approach depends on having a Q and a Qₙ output that are always opposite so that the determinative state chart of FIG. 8 is achieved. In circuits having a flip-flop with only a Q output, a Qₙ output can be created by adding an inventer to a second line from the Q output and feeding it back to the pull-down circuit 615. An advantage of this embodiment is not only the increased speed in which a test may be accomplished, but the reduced need for dynamic input/output control and the circuitry associated with that input/output control. Although an output buffer 614 is shown as disconnected in the example of FIG. 6, it is shown merely to emphasize the difference between the examples of FIGS. 3 and 5 and no output buffer at all is necessary in one embodiment.

In the embodiments discussed above, a reduction in test pins necessary for an integrated circuit package has been described where three or two pins may be used in place of the typically necessary four pins for testing a particular logical scan chain. For each of the embodiments above, each scan chain would need its own input/output test data pin and thus an additional pin would be needed for each additional scan chain to be tested, however the need for separate input and output test pins, or for a scan enable external pin in the version of FIG. 5, may be avoided.

### Reduction of External Test Pins to 1

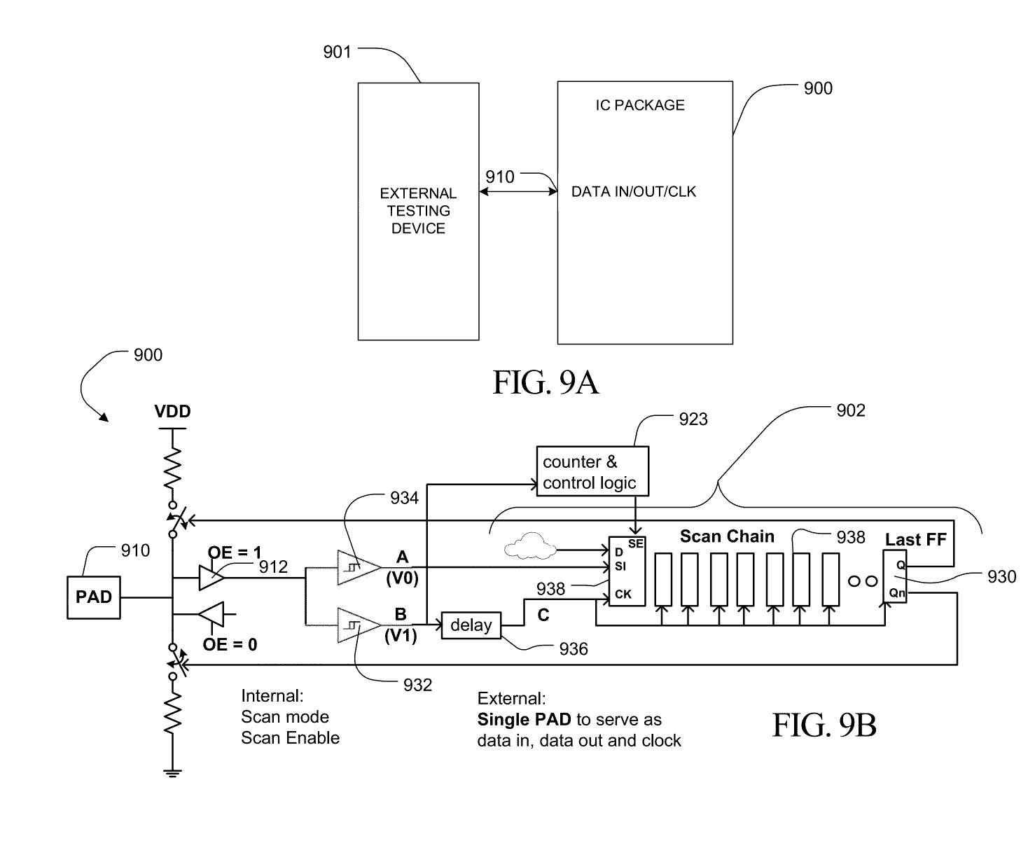

In alternative embodiments discussed below, the number of test pins may be further reduced from the embodiments set forth above to eliminate an external test clock pin and leave a single input/output data pin per scan chain. As was the case with the removal of a scan enable pin in the embodiment of FIG. 5, in order to remove the need for an external clock pin, additional circuitry is necessary in the integrated circuit to generate the clock signal internally. Referring now to FIGS. 9-11, an integrated circuit 900 having a single test pin (per scan chain) is illustrated. This single pin would be pad 908 which acts as the one external interface for data in, data out and the clock. The integrated circuit 900 includes one or more scan chains 902 and an input buffer 912 that works in conjunction with current generation from the last flip-flop 930 (Last FF) to allow a testing device connected to the external pad 910 (or pin) to sense output test data at the same time that input test data is being entered via the pad. The internal clocking that allows reduction of yet another pin as compared to the integrated circuit versions of FIG. 5 or 6 is accomplished by including a set of two Schmitt triggers 932, 934 inside the integrated circuit 900 connected in parallel to the output of the input buffer 912.

The two Schmitt triggers 932, 934 are configured to trigger at different voltage thresholds (V0 and V1) and, in addition, a programmable delay line 936 is connected between the first Schmitt trigger 934 and the clock inputs of each of the flip-flops 938 in the scan chain 902. The programmable delay line 936 may be a circuit, such as a series of buffers that can be connected or bypassed individually, having a signal delay value capable of permitting flip-flops to capture data before the clock signal is delivered to the scan chain 902. Other known delay line circuits may be utilized, and in one embodiment the delay line may be fixed rather than programmable. The external testing device (not shown) connected to pad 908 via the single external test pin 910 is configured to send a test data signal via the pad 910 at a first voltage level to trigger the first Schmitt trigger 932 and a second voltage level to trigger both the first and second Schmitt triggers 932, 934. Specifically, the Schmitt trigger 932 that is assigned to generate/repeat the clock signal inside the integrated circuit 900 would receive a voltage level that would trigger a clock signal output every cycle, but the scan-in data input of the first flip-flop in the chain 902 would only be driven to a logical high when the voltage of the input signal sent to the pad 910 by the external testing device 102 is above a higher threshold that triggers the second Schmitt trigger circuit 934. Thus, both Schmitt triggers would work in tandem to generate data and scan clock pulses based on different input voltages.

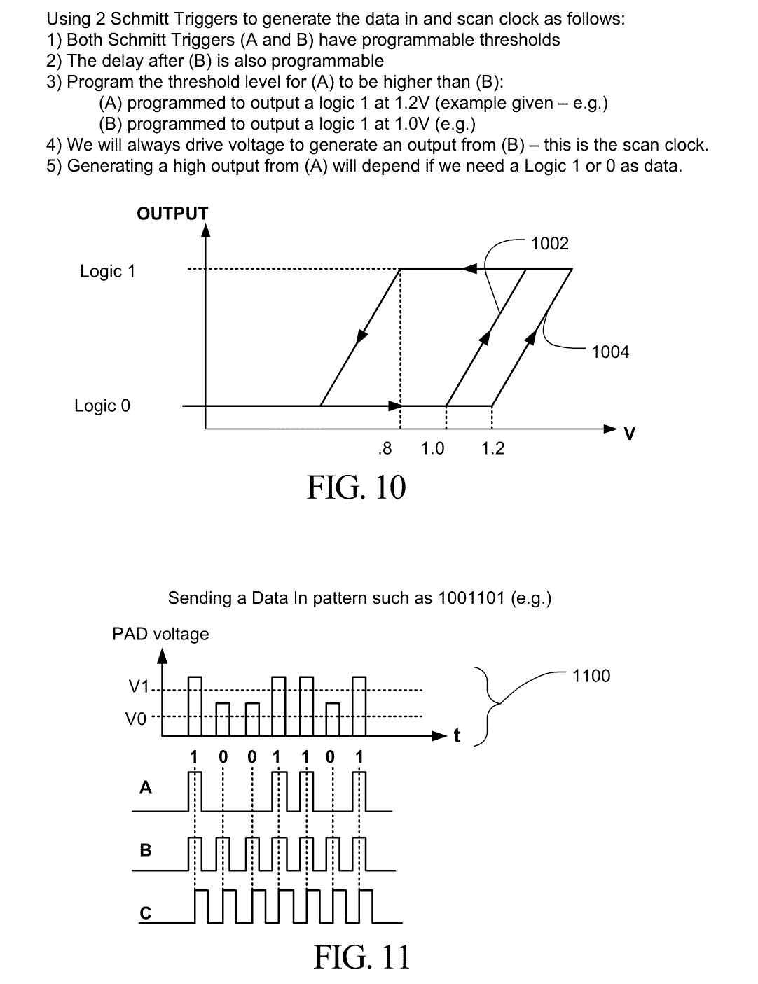

The voltage levels and different Schmitt trigger levels resulting in outputs that represent a logic 0 or logic 1, in addition to a continual clock signal, are better described with reference to FIGS. 10 and 11. As shown in FIG. 10, the voltage cycle for the second Schmitt trigger 934 is set to be higher than the threshold voltage level for the first Schmitt trigger 932. For example, if the first Schmitt trigger response 1002 was programmed to trigger at a logic level 1 (high output) in response to an input voltage of 1.0V, the second Schmitt trigger could be programmed at a higher threshold voltage of, for example 1.2V, to trigger a logic level 1 (high output) from the second Schmitt trigger 934. The testing device 102 would always supply a voltage of at least 1.0V to generate an output from the second Schmitt trigger, because the second Schmitt trigger 934 is acting as the scan clock signal buffer for the test. The higher generated output from the second Schmitt trigger 934 would only be activated by the testing device via a higher input voltage, of at least 1.2 V in this example, at the pad 910, if there is a need for a logical 1.

Referring to FIG. 11, an example of a data pattern being transmitted in by external testing device 102 to the pad of the integrated circuit 900 of FIG. 9 via an input signal pulse pattern 1000 delivered to the single pin 910 of the integrated circuit 900 is illustrated. The input signal pulse pattern 1100 sent in is a logical “1001101” which causes, as seen in trace A, logical high (1) pulses to be generated by the second Schmitt trigger 934 when the input voltage is at or above V1 (1.2V in this example) needed to trigger the second Schmitt trigger, and logical low (0) when the input voltage from the external test device 102 is less than V1. The second trace, trace B, is the pulse being sent out from the first Schmitt trigger 932 in response to the testing device sending timed pulses of V0 (1.0V in this example) or more that triggers the lower threshold of the first Schmitt trigger 932. The third trace (C) in FIG. 11 illustrates the delayed output from the first Schmitt trigger 932 (a delay of the voltage level seen in trace B in FIG. 11) that is output from the delay line 936. The delayed clock pulse trace C is necessary to allow any test data input coming through the second Schmitt trigger 934 to reach the scan chain 902 (and the data passing from each flip-flop to reach the next in the chain) prior to the clock signal capture of the data from the second Schmitt trigger. This delay is necessary so that the data from the second Schmitt trigger and the clock signal from the first Schmitt trigger 932 do not reach the scan chain simultaneously, potentially causing an instability or other erroneous read of data at the scan chain. Although the offset provided by the delay line 936 between the first Schmitt trigger 932 and the scan chain is illustrated in trace C of FIG. 11 as delaying the clock pulse from going high until approximately halfway through the data pulse high of trace A, the delay line 936 may be configured for other offset amounts in different embodiments.

As seen in FIGS. 9-11 an integrated circuit design 900 is provided that reduces testing inputs to a single external pin 910 allows a single input signal 1100 act as both the test data and clock. The internal scan enable circuitry 923, which may be the same as discussed with respect to the integrated circuit of FIG. 5, receives the clock outputs triggered from the first Schmitt trigger 932, prior to the delay line 936, and controls the generation of a scan enable signal. The scan enable signal is sent to each of the flip-flops in the scan chain 902, where the signal is set high for a frame of test data (the number of clock pulses equal to the number of flip-flops in the (longest) scan chain) and subsequently set low for the number of clock pulses necessary to store the data during a capture phase, as discussed with respect to the prior integrated circuit embodiments.

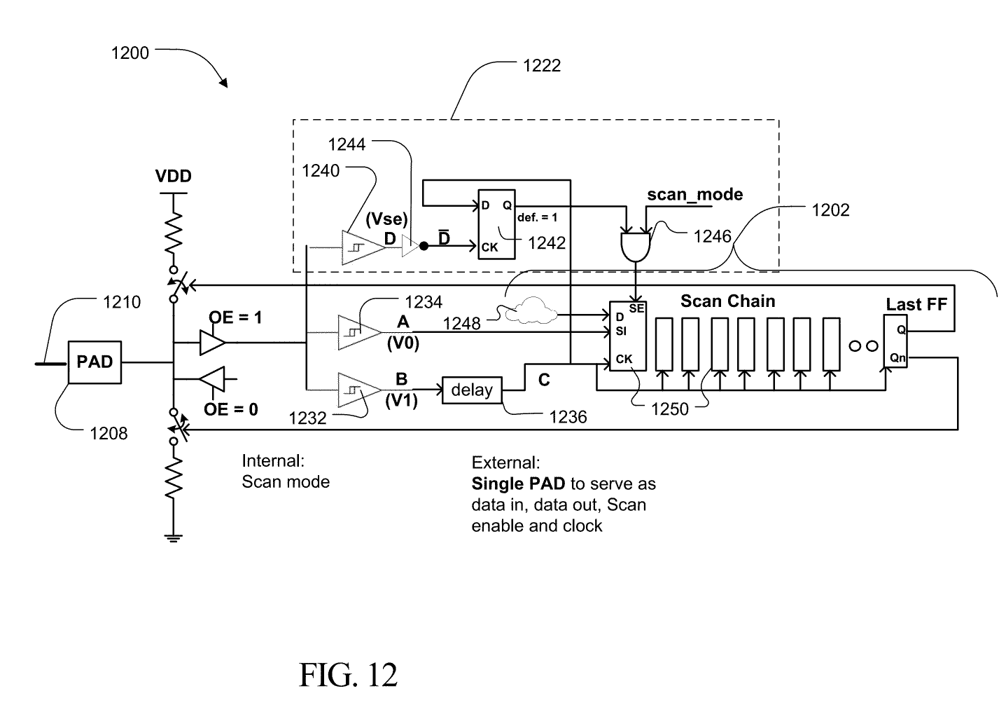

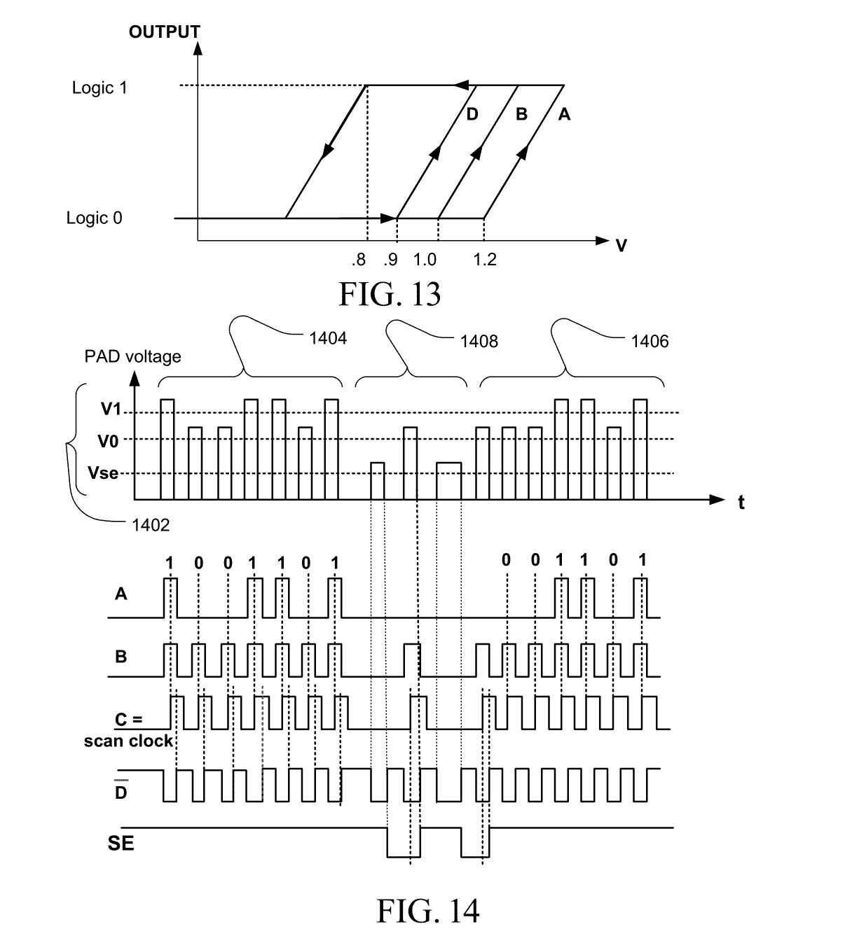

In yet another embodiment of a reduced test pin configuration for an integrated circuit, FIGS. 12-14 illustrate a variation of the single test pad embodiment of FIGS. 9-11. The integrated circuit 1200 of FIG. 122 shows essentially the same integrated circuit 900 as discussed with respect to FIG. 9, and also includes only a single pad 1208 attached to a single external pin 1210 but also adds a scan enable circuit 1222 that is triggered, like the clock in FIG. 9, directly by the external testing device signals via a Schmitt trigger 1240 reached at the single external pin 1210/pad 1208 of the integrated circuit 1200. In FIG. 12, the integrated circuit 1200 adds an additional third Schmitt trigger 1240, to first and second Schmitt trigger circuits 1232, 1234 having functions identical to those of the integrated circuit 900 of FIG. 9. The third Schmitt trigger 1242 is added to generate scan enable logic and requires fewer flip-flop circuits (here, just a single flip-flop 1242) and therefore may require a less complicated integrated circuit design. All three Schmitt triggers have programmable thresholds. Additionally, the delay on the Schmitt trigger 1232 generated clock signal is programmable via a delay line 1236.

Similar to the staggered threshold levels for the Schmitt triggers of FIG. 9, the integrated circuit 1200 of FIG. 12 uses different threshold levels for the first and second Schmitt triggers 1232, 1234 as well as the third Schmitt trigger 1240. In one embodiment, the first Schmitt trigger 1232 may be programmed to output a logical 1 at 1.0V (voltage threshold V_{O}), the second Schmitt trigger 1234 may be configured to output a logical 1 at 1.2V (voltage threshold V₁) and the third Schmitt trigger 1240, tied to the scan enable circuit 1222, may be programmed to output a logical 1 at 0.9V (voltage threshold V_{SE}). These voltage levels are provided by way of example and various other triggering thresholds (V_{O}, V₁ and V_{SE}) for the Schmitt triggers can be implemented in other embodiments.

In testing, the external testing device 901 will always provide a signal at V_{SE} to generate a scan enable output from the third Schmitt trigger. This will clock the scan enable flip-flop 1242. The scan enable flip-flop 1242 samples at the falling edge, due to the inverter 1244 placed after the third Schmitt trigger, and the scan enable flip-flop 1244 is provided with a default value of 1. The generation of the scan clock will again be the result of the output of the first Schmitt trigger 1232 based on received input voltage greater than or equal to V_{O} (here, one volt). When the testing device 901 wants to input a logical 1 for the test data (logical 1 output) the pulse is transmitted to the pin 1210 of the integrated circuit 1200 at a level greater than or equal to V₁ so the second Schmitt trigger 1234 will output a high output (logical 1) concurrently with the output highs of the first and third Schmitt triggers 1232, 1240. The staggered input logic triggers of each of the Schmitt triggers are illustrated in FIG. 13 where the input voltage trigger level of the third Schmitt trigger 1240 is shown at 1302, the input voltage trigger level of the first Schmitt trigger 1232 is shown at 1304, and the input voltage trigger level of the third Schmitt trigger 1234 is shown at 1306.

The resulting waveform from the external testing device 901 to represent input test data of 1001101 (the same data pattern as provided with respect to FIG. 9) followed by two capture period clock cycles and then input test data 001101 is illustrated in FIG. 14, along with the resulting waveforms at points A, B, C, D and SE (SE as seen at the output of the AND logic 1246) identified in the circuit 1200. When the input voltage at the external pin 1210 of the integrated circuit receives a voltage at level V₁, a logical 1 is being sent. This voltage level V₁ is greater than both V_{SE} and V_{O} representing the scan enable and clock thresholds so that the single pulse at or above V₁ represents the clock, the scan enable and the data input of 1. Similarly, an input voltage between V₁ and V_{O} for the input pulse represents a logical 0 for the test data while still triggering the scan clock and scan enable outputs of the first and third Schmitt triggers 1232, 1240. It should be noted that the test pin inputs 1402 are intended merely as a sample of an end portion of a hypothetical first input test data sequence (frame) 1404 and the beginning of a hypothetical second input test data sequence (frame) 1406 to test a scan chain separated by a capture period 1408. In one embodiment, the total length of each test sequence may be longer or shorter than the portions illustrated, and each complete test sequence would be equal in length for a particular scan chain as the length (number of data pulses) would need to equal the number of flip-flops in the scan chain.

In order to measure the test result output, which represents the results of the input test data after clocking it through the random logic 1248 connected with flip-flops 1250 in the scan chain 1202, the same current sensing mechanism described in greater detail with respect to the integrated circuit embodiments of FIGS. 6 and 9 is implemented so that test result output from the final flip-flop (Last FF) may be sensed via currents at the single test pin 1210 simultaneously with the voltage inputs being provided to the test pin 1210. As discussed above, although random logic 1248 is only shown as connected to the first flip-flop 1250 in the scan chain 1203, this is for simplicity of illustration and one or more other of the remaining flip-flops 1250 in the scan chain 1202 may be connected to one or more different groups of random logic 1248 in various implementations.

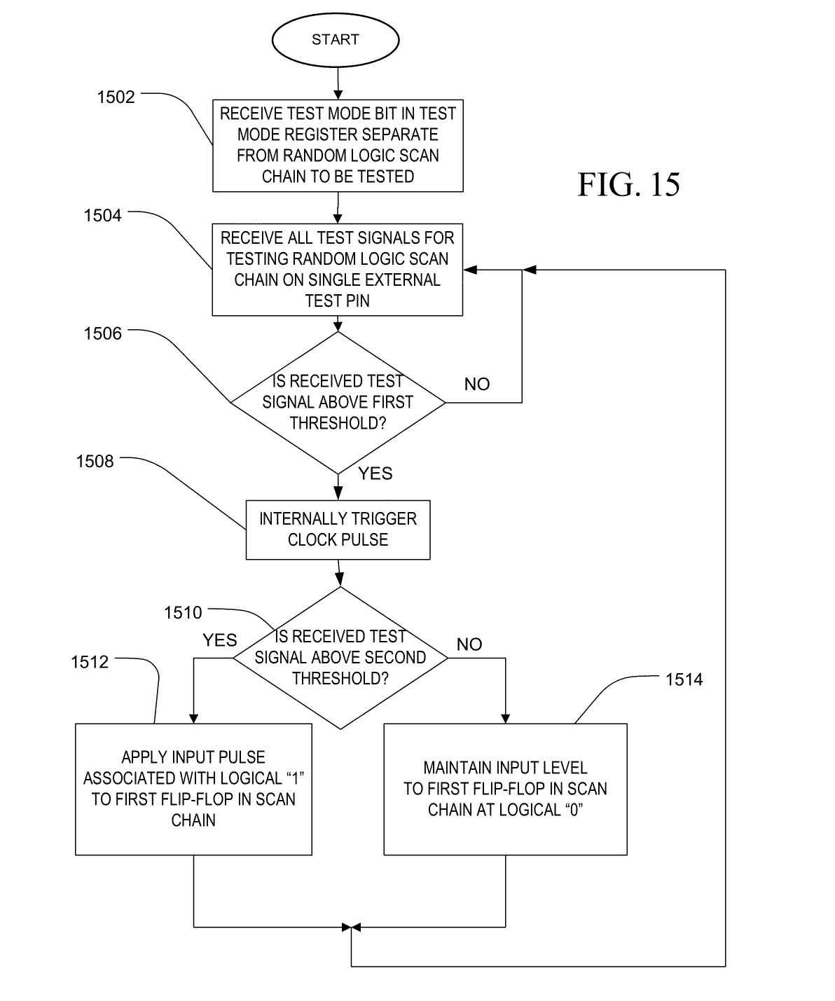

Referring to FIG. 15, a method of testing integrated circuits 900, 1200 having a single test pin configuration is set out. The external testing device 901, which may be any system programmable to provide, and measure the response to, input pulses for the various logic combinations known in a particular integrated circuit design, first transmits a test mode bit to the integrated circuit 900, 1200 to place the integrated circuit into a test mode (at 1502). The testing device then sends to, and the integrated circuit thus receives at, the single test pin the various clock and test signals (at 1504). When in the test mode, the integrated circuit will wait for a signal at the test pin. If the test pin receives a signal that is above a first threshold (e.g. the clock voltage threshold of the first Schmitt trigger), the first Schmitt trigger will generate a clock pulse output to the scan chain (at 1506, 1508). Otherwise, the integrated continues to wait until a signal having a voltage level at least at the first threshold arrives. If the signal that arrives is also above a second threshold (e.g. the logical 1 threshold voltage of the second Schmitt trigger connected to the first flip-flop in the scan chain) then a logical 1 is presented to the first flip flop in addition to the clock signal also being presented to the scan chain (at 1510, 1512). Should the signal only be above the first threshold, but not above the second, then the second Schmitt trigger will present a logical 0 to the input of the first flip-flop (at 1514). The internal generation of a scan enable signal in the process of FIG. 15 may either be accomplished by a divider and logic circuit as in FIG. 9, or as in FIG. 12 with a third Schmitt trigger 1240 configured to output the appropriate scan enable signal with fewer flip-flops than needed in the counter and logic circuit 923 using a lower threshold than the first Schmitt trigger threshold used for the clock signal.

Systems and methods have been disclosed for reducing the external pins necessary on an integrated circuit to test random logic in the integrated circuit. The integrated circuit may be any of a number of types of integrated circuitry having scan chains of random logic, including memory circuits such as a non-volatile NAND flash memory integrated circuits, or other types of memory or non-memory circuits. Embodiments for reducing external testing pins necessary for non-destructive testing of integrated circuit packages may be include a 3 pin per arrangement where the input and output test data is combined on a single pin by adding I/O control circuitry into the integrated circuit so that the input and output data may be alternately cycled into and out of the integrated circuit. Other embodiments include further reducing the external test pins from 3 to 2 by additionally incorporating logic and divider circuitry to use the clock signal and replace the need for an external scan enable signal input pin. The two-pin embodiment may be further enhanced to increase testing speed, by implementing a current sensing test data output that permits simultaneous entry of test input data via voltage inputs from the external testing device and sensing of the test output data from the last flip-flop in the scan chain over the single input/out data pin via current changes, in contrast to the alternate periods of input and output data transmission using only voltages. Finally, single external test pin embodiments are provided where test data input/output and clock signals are all sharing the same external pin.

It is therefore intended that the foregoing detailed description be regarded as illustrative rather than limiting, and that it be understood that it is the following claims, including all equivalents, that are intended to define the spirit and scope of this invention.

We claim:

1. An integrated circuit having reduced test pin requirements for logic testing, the integrated circuit comprising:
at least one scan chain, the at least one scan chain comprising a plurality of sequentially connected flip-flop circuits;
digital logic circuitry connected to at least one of the plurality of flip-flop circuits in the at least one scan chain;
a clock input pin configured to receive an externally generated clock signal from an external test device; and
a test data pin, the test data pin configured to receive test input data from the external test device and to receive test output data generated internally at the integrated circuit by the at least one scan chain, the test output data corresponding to the received test input data after clocking the test input data through the scan chain.

2. The integrated circuit of claim 1, comprising:
an input-output control circuit connected to the test data pin, the input-output control circuit configured to toggle a mode of the test data pin between an input-only mode, wherein test input data from the external test device is applied to the scan chain, and an output-only mode, wherein test output data generated by the scan chain is applied to the test data pin.

3. The integrated circuit of claim 2, wherein the input-output circuit is configured to toggle the mode after a predetermined number of cycles of the externally generated clock signal received at the clock input pin, the predetermined number of cycles comprising a total number of flip-flops in the scan chain.

4. The integrated circuit of claim 3, further comprising a test scan enable circuit in communication with the scan chain, the test scan enable circuit configured to place the scan chain in a test mode in response to receipt of a test scan enable signal from the external test device via a scan enable signal pin on the integrated circuit.

5. The integrated circuit of claim 3, further comprising a scan enable signal circuit positioned internally to the integrated circuit and configured to internally generate a scan enable signal in response to receipt of the externally generated clock signal, the test scan enable circuit in communication with the scan chain and configured to place the scan chain in a test mode in response to a test mode bit.

6. The integrated circuit of claim 5, wherein the scan enable signal circuit comprises a counter circuit configured to maintain a scan enable signal at a first output level for a first predetermined number of clock cycles, and at a second output level for a second predetermined number of clock cycles, the first predetermined number of clock cycles corresponding to a number of flip-flop circuits in the scan chain, and the second predetermined number of clock cycles corresponding to number of clock cycles necessary to capture test data.

7. The integrated circuit of claim 1, wherein the digital logic circuitry comprises at least one of an AND, OR, NAND or NOR digital logic circuit.

8. The integrated circuit of claim 1, further comprising:
an input buffer connected to the test data pin, the input buffer circuit configured provide input voltages representing test data received from the external testing device to the scan chain; and
an output data connection from a last flip-flop in the scan chain to the test data pin, the output current connection configured to permit simultaneous current output signals to the test data pin while test data voltage signals are being received at the test data pin.

9. A method of testing logic with a minimal number of dedicated test pins, the method comprising:
in an integrated circuit having at least one scan chain, the at least one scan chain comprising:
a plurality of sequentially connected flip-flop circuits; and
digital logic circuitry connected to at least one of the plurality of flip-flop circuits in the at least one scan chain; and
receiving an externally generated clock signal at an external clock input pin connected to the integrated circuit; and
in response to a receipt of a predetermined number of clock cycles at the external clock input pin, automatically alternating an operating mode of a test data pin between an input mode, wherein test input data from the external test device is received, and an output mode, wherein test output data generated internally at the integrated circuit by the at least one scan chain test input data is output from the integrated circuit via the test data pin.

10. The method of claim 9, wherein alternating the operating mode comprises an input-output control circuit in the integrated circuit:
powering an input buffer amplifier connecting the test data pin to a first flip-flop in the scan chain in an input-only mode, wherein test input data from the external test device is applied to the scan chain;
powering an output power buffer connecting the test pin to a last flip-flop of the scan chain in an output-only mode, wherein test output data generated by the scan chain is applied to the test data pin; and
wherein only one of the input buffer or output buffer are powered at a time

11. The method of claim 10, wherein the input-output circuit alternates the mode between the input-only mode and the output-only mode after the predetermined number of clock cycles received at the clock input pin, and wherein the predetermined number of clock cycles comprise a number equal to a total number of flip-flops in the scan chain.

12. The method of claim 10, further comprising, responsive to a test scan enable signal received from an external test device at an external scan enable pin on the integrated circuit, placing the scan chain in a test mode.

13. The method of claim 10, further comprising in response to receiving the externally generated clock signal, internally generating a scan enable signal internally to the integrated circuit utilizing a test scan enable circuit positioned internal to the integrated circuit, wherein the test scan enable circuit is in communication with the scan chain.

14. The method of claim 13, wherein generating the scan enable signal comprises counting clock cycles received and maintaining a scan enable signal at a first output level for a first predetermined number of clock cycles, and maintaining the scan enable signal at a second output level for a second predetermined number of clock cycles, the first predetermined number of clock cycles corresponding to a number of flip-flop circuits in the scan chain, and the second predetermined number of clock cycles corresponding to number of clock cycles necessary to capture test data.

15. An integrated circuit having reduced test pin requirements for logic testing, the integrated circuit comprising:
at least one scan chain, the at least one scan chain comprising a plurality of sequentially connected flip-flop circuits;
digital logic circuitry connected to at least one of the plurality of flip-flop circuits in the at least one scan chain;
a single external test pin in communication with the at least one scan chain and digital logic circuitry via a first signal generation circuit and a second signal generation circuit;
wherein an output of the first signal generation circuit is in communication with a clock input of the plurality of flip-flop circuits in the scan chain and is responsive to receipt of a signal at the single external test pin having at least a first voltage level to generate a clock pulse for the plurality of flip-flop circuits; and
wherein an output of the second signal generation circuit is in communication with a data input of only a first of the plurality of flip-flop circuits and the second signal generation circuit is responsive to receipt of the signal at the single external test pin to generate a logical high input for the first flip-flop circuit only when the signal has at least a second voltage level that is greater than the first voltage level.

16. The integrated circuit of claim 15, further comprising:
a third signal generation circuit, the third signal generation circuit having an output in communication with a scan enable input of the scan chain and configured to generate a scan enable signal when the signal received at the external test pin has a voltage greater than or equal to a third voltage level, wherein the third voltage level is less that the first voltage level.

17. The integrated circuit of claim 15, wherein the first signal generation circuit comprises a first Schmitt trigger circuit and the second signal generation circuit comprises a second Schmitt trigger circuit.

18. The integrated circuit of claim 17, further comprising a signal delay line positioned between the output of the first Schmitt trigger circuit and the clock input of the plurality of flip-flop circuits in the scan chain, the signal delay line configured to delay the clock pulse generated by the first Schmitt trigger such that output from the second Schmitt trigger reaches the first flip flop prior to the clock pulse generated by the first Schmitt trigger.

19. The integrated circuit of claim 16, wherein:
the first signal generation circuit comprises a first Schmitt trigger circuit, the second signal generation circuit comprises a second Schmitt trigger circuit, and the third signal generation comprises a third Schmitt trigger circuit.

20. The integrated circuit of claim 15, further comprising an output data connection from a last flip-flop circuit in the scan chain to single external test data pin, the output current data connection configured to permit simultaneous current output signals to the single external test pin while test data voltage signals are being received at the test pin.
